(19) United States
(12) Patent Application Publication
(10) Pub. No.: US 2024/0071762 A1
(43) Pub. Date: Feb. 29, 2024

(54) INTEGRATED CIRCUIT HAVING AN IMPROVED METAL LAYER

(71) Applicant: TEXAS INSTRUMENTS INCORPORATED, Dallas, TX (US)

(72) Inventors: JOSE DANIEL TORRES, ANGELES CITY (PH); KATLEEN FAJARDO TIMBOL, SICHUAN (CN)

(21) Appl. No.: 17/893,746

(22) Filed: Aug. 23, 2022

(51) Int. Cl. H01L 21/027; H01L 21/48; H01L 23/498

(52) U.S. Cl. CPC H01L 21/0274; H01L 21/4853; H01L 23/49816; H01L 23/49838; H01L 23/49866

(57) ABSTRACT

An electronic device includes a substrate having electrical circuits and/or electronic devices disposed thereon. Metal traces are formed on the substrate and include feet on each side of the metal traces that flare outward in opposite directions from each other where the metal traces overlie the substrate. A dielectric layer is formed on the substrate and a portion of the metal traces, and an interconnect is disposed on the metal traces.

### TECHNICAL FIELD

The present disclosure relates to an electronic device and more specifically, to an integrated circuit (IC) that includes an improved metal layer.

### BACKGROUND

Integrated circuit (IC) packages (e.g., wafer chip scale package (WCSP)) include a metal layer deposited on the wafer. The metal layer connects with electrical circuits and/or device (e.g., transistors) on the wafer and provides an electrical connection from the wafer to external electronic devices (e.g., printed circuit boards (PCB)). Deposition of the metal layer, however, creates issues that result in open circuits and current leakage in the IC package. Specifically, a flare out or a foot developed from the patterning of a photoresist material layer prior to deposition of the metal layer results in undercuts formed in metal layer where the metal layer meets the wafer. The undercuts result in open circuits and current leakage in the IC package and a decrease in tolerance for pattern alignment due to exposure of seed layers.

### SUMMARY

In described examples, a method includes providing a substrate, the substrate including electrical circuits and/or electronic devices disposed thereon. At least one photoresist material layer is patterned and overlies the substrate, such that the at least one photoresist material layer includes at least one opening formed therein. The at least one photoresist material layer includes undercuts formed on each side of the at least one opening where the at least one photoresist material layer overlies the substrate. A metal film is deposited in the at least one opening formed by the at least one photoresist material layer to form a metal trace. The metal trace forms a foot in the undercuts in the at least one opening formed by the at least one photoresist material layer. A dielectric layer is formed over the substrate and an interconnect is deposited on the metal trace.

In another described example, an electronic device includes a substrate having electrical circuits and/or electronic devices disposed thereon. Metal traces are formed on the substrate and include feet on each side of the metal traces that flare outward in opposite directions from each other where the metal traces overlie the substrate. A dielectric layer is formed on the substrate and a portion of the metal traces, and an interconnect is disposed on the metal traces.

### BRIEF DESCRIPTION OF THE DRAWINGS

FIG. 1 is a side view of an example electronic device.

FIG. 2 is a side view of another example electronic device.

FIG. 3 is a side view of still another example electronic device.

FIG. 4 illustrates a side view of a substrate in the early stages of fabrication of an electronic device of FIG. 1.

FIG. 5 illustrates a side view of the electronic device of FIG. 4 after undergoing a first metal deposition.

FIG. 6 illustrates a side view of the electronic device of FIG. 5 undergoing a first photoresist material layer patterning.

FIG. 7 illustrates a process of fabricating undercuts in the first photoresist material layer of FIG. 6.

FIG. 8 illustrates a side view of the electronic device of FIG. 7 undergoing an electroplating process.

FIG. 9 illustrates a side view of the electronic device of FIG. 8 after undergoing an etch process and stripping of the first photoresist material layer.

FIG. 10 illustrates a side view of the electronic device of FIG. 9 after undergoing a metal etch process to remove metal seed layers.

FIG. 11 illustrates a side view of the electronic device of FIG. 10 after undergoing a process of depositing a dielectric or passivation layer.

FIG. 12 illustrates a side view of the electronic device of FIG. 11 after undergoing a patterning process.

FIG. 13 illustrates a side view of the electronic device of FIG. 12 after undergoing a second metal deposition.

FIG. 14 illustrates a side view of the electronic device of FIG. 13 undergoing a second photoresist material layer patterning.

FIG. 15 illustrates a side view of the electronic device of FIG. 14 after undergoing another electroplating process.

FIG. 16 illustrates a side view of the electronic device of FIG. 15 after undergoing an etch process and stripping of the second photoresist material layer.

FIG. 17 illustrates a side view of the electronic device of FIG. 16 after undergoing a deposition of an interconnect.

FIG. 18 illustrates a side view of a substrate in the early stages of fabrication of an electronic device of FIG. 2.

FIG. 19 illustrates a side view of the electronic device of FIG. 18 undergoing metal deposition.

FIG. 20 illustrates a side view of the electronic device of FIG. 19 undergoing a first photoresist material layer patterning.

FIG. 21 illustrates a side view of the electronic device of FIG. 20 undergoing a second photoresist material layer patterning.

FIG. 22 illustrates a side view of the electronic device of FIG. 21 undergoing an electroplating process.

FIG. 23 illustrates a side view of the electronic device of FIG. 22 after undergoing an etch process and stripping of the first and second photoresist material layers.

FIG. 24 illustrates a side view of the electronic device of FIG. 23 after undergoing a metal etch process to remove metal seed layers.

FIG. 25 illustrates a side view of the electronic device of FIG. 24 after undergoing a process of depositing a dielectric or passivation layer.

FIG. 26 illustrates a side view of the electronic device of FIG. 25 after undergoing a patterning process.

FIG. 27 illustrates a side view of the electronic device of FIG. 26 after undergoing a second metal deposition.

FIG. 28 illustrates a side view of the electronic device of FIG. 27 undergoing a third photoresist material layer patterning.

FIG. 29 illustrates a side view of the electronic device of FIG. 28 after undergoing another electroplating process.

FIG. 30 illustrates a side view of the electronic device of FIG. 29 after undergoing an etch process and stripping of the third photoresist material layer.

FIG. 31 illustrates a side view of the electronic device of FIG. 30 after undergoing a deposition of an interconnect.

### DETAILED DESCRIPTION

Disclosed herein is an electronic device, more specifically, an integrated circuit (IC) package and method of fabricating the IC package. The IC package (e.g., wafer chip scale package (WCSP)) includes a metal layer deposited on a wafer. The metal layer is comprised of metal traces that provide an electrical connection between the wafer and external electronic devices (e.g., printed circuit board (PCB)). The metal traces are deposited such that each metal trace includes feet that flare out on each side of the metal trace where the metal trace contacts the wafer. The feet facilitate a reduction in a width of the metal traces as well as a reduction of spacing between adjacent metal traces thereby allowing a decrease in a size of the IC package or an increase in the amount of metal traces in the IC package. In addition, the feet mitigate open circuits and current leakage in the IC package.

The method includes depositing and patterning a specially formulated photoresist material layer over a wafer. The photoresist material layer undergoes a heating process that includes a pattern exposure, a post exposure bake, and a pattern development. The heating process to the photoresist material layer forms undercuts to the photoresist material layer in openings where the photoresist material layer overlies the wafer. Thus, when the metal layer is deposited on the wafer, metal traces are formed in the openings of the photoresist material layer. During deposition of the metal layer, the metal for the metal traces is deposited in the undercuts of the photoresist material layer thereby forming feet on each side of the metal traces thereby improving the electrical properties of the IC package.

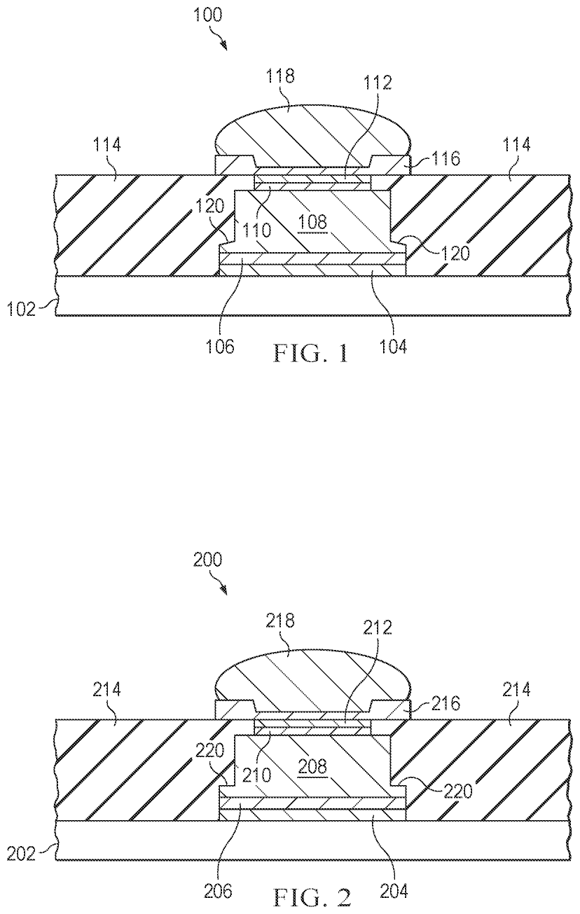

FIG. 1 is a side view of an example electronic device (e.g., integrated circuit (IC) package) 100 comprised of a substrate 102, seed layers 104, 106, a metal film or layer (e.g., copper) comprised of metal traces 108, interconnection metal layers 110, 112, a dielectric layer 114, an under bump metallization layer (UBM) 116, and an interconnect 118. The electronic device 100 can be comprised of an IC package including, but not limited to a WCSP, a Quad Flat No-Lead (QFN) package, a Bond Over Active Circuit (BOAC) package, etc.

The substrate 102 is comprised of a wafer (e.g., silicon wafer) and includes active circuits and/or active electronic devices (e.g., transistors) embedded therein and/or on a surface thereof. The seed layers 104, 106 are thin film metal layers comprised of titanium/tungsten (TiW) and copper (Cu) respectively. The seed layers 104, 106 improve the adhesion between the metal traces 108 and the substrate 102. The metal traces 108 are deposited on the seed layers 104, 106. Each metal trace 108 is deposited on the seed layers 104, 106 to include feet 120 that flare outward in opposite directions from each other where the metal trace 108 overlies the substrate 102 and contacts the seed layers 104, 106. In this example, the feet 120 are formed by a specially formulated photoresist material layer that undergoes a heating process including a post exposure bake such that undercuts are formed in the photoresist material layer where the photoresist material layer overlies the substrate 102 and contacts the seed layers 104, 106. As mentioned above, the addition of the feet 120 prevents open circuits and current leakage in the IC package while facilitating a reduction in a width of the metal traces as well as a reduction of spacing between adjacent metal traces thereby allowing a decrease in a size of the IC package or an increase in the amount of metal traces in the IC package.

The dielectric layer 114 can be made from a polymer, such as polyimide or another suitable material such as silicon oxide or silicon nitride. The interconnection metal layers 110, 112 are thin film metal layers comprised of titanium/tungsten (TiW) and copper (Cu) respectively and improve the adhesion between the metal trace 108 and the UBM layer 116. The UBM layer 116 is a metal layer (e.g., copper, nickel) between the metal traces 108 and the interconnect 118. The UBM layer 116 forms the electrical connection between the metal traces 108 and interconnect 118 and serves as a barrier to eliminate unwanted diffusion. The interconnect 118 is a solder bump that connects to an external electronic device such a PCB. The interconnect 118 provides the electrically conductive path to carry electrical current between the substrate 102 and the external device.

FIG. 2 is a side view of another example of an electronic device (e.g., integrated circuit (IC) package) 200 comprised of a substrate 202, seed layers 204, 206, a metal film or layer (e.g., copper) comprised of metal traces 208, interconnection metal layers 210, 212, a dielectric layer 214, an under bump metallization (UBM) layer 216, and an interconnect 218. The electronic device 200 can be comprised of an IC package including, but not limited to a WCSP, a Quad Flat No-Lead (QFN) package, a Bond Over Active Circuit (BOAC) package, etc.

The substrate 202 is comprised of a wafer (e.g., silicon wafer) and includes active circuits and/or active electronic devices (e.g., transistors) embedded therein and/or on a surface thereof. The seed layers 204, 206 are thin film metal layers comprised of titanium/tungsten (TiW) and copper (Cu) respectively. The seed layers 204, 206 improve the adhesion between the metal traces 208 and the substrate 202. The metal traces 208 are deposited on the seed layers 204, 206. Each metal trace 208 is deposited on the seed layers 204, 206 to include feet 220 that flare outward in opposite directions from each other where the metal trace 208 overlies the substrate and contacts the seed layers 204, 206. In this example, the feet 220 are formed by depositing and patterning a first photoresist material layer on the seed layers 204, 206 where the first photoresist material layer includes first openings. A second photoresist material layer is deposited and patterned on the first photoresist material layer. The second photoresist material layer includes second openings that are aligned with the first openings. The second openings, however, have a smaller width than the first openings thereby forming an undercut in a stacked formation of both the first and second photoresist material layers. The undercut is filled with metal from the deposition of the metal film thereby forming the feet 220 of the metal traces 208. As mentioned above, the addition of the feet 220 prevents open circuits and current leakage in the IC package while facilitating a reduction in a width of the metal traces as well as a reduction of spacing between adjacent metal traces thereby allowing a decrease in a size of the IC package or an increase in the amount of metal traces in the IC package.

The dielectric layer 214 can be made from a polymer, such as polyimide or another suitable material such as silicon oxide or silicon nitride. The interconnection metal layers 210, 212 are thin film metal layers comprised of titanium/tungsten (TiW) and copper (Cu) respectively and improve the adhesion between the metal traces 208 and the UBM layer 216. The UBM layer 216 is a metal layer (e.g., copper) between the metal traces 208 and the interconnect 218. The UBM layer 216 forms the electrical connection between the metal traces 208 and interconnect 218 and serves as a barrier to eliminate unwanted diffusion. The interconnect 218 is a solder bump that connects to an external electronic device such a PCB.

FIG. 3 is a side view of still another example of an electronic device (e.g., integrated circuit (IC) package) 300 comprised of a substrate 302, seed layers 304, 306, a metal film or layer (e.g., copper) comprised of metal traces 308, interconnection metal layers 310, 312, a dielectric layer 314, an under bump metallization (UBM) layer 316, and an interconnect 318. The electronic device 300 can be comprised of an IC package including, but not limited to a WCSP, a Quad Flat No-Lead (QFN) package, a Bond Over Active Circuit (BOAC) package, etc.

The substrate 302 is comprised of a wafer (e.g., silicon wafer) and includes active circuits and/or active electronic devices (e.g., transistors) embedded therein and/or on a surface thereof. The seed layers 304, 306 are thin film metal layers comprised of titanium/tungsten (TiW) and copper (Cu) respectively. The seed layers 304, 306 improve the adhesion between the metal traces 308 and the substrate 302. The metal traces 308 are deposited on the seed layers 304, 306. The dielectric layer 314 can be made from a polymer, such as polyimide or another suitable material such as silicon oxide or silicon nitride. The interconnection metal layers 310, 312 are thin film metal layers comprised of titanium/tungsten (TiW) and copper (Cu) respectively and improve the adhesion between the metal traces 308 and the UBM layer 316. The UBM layer 316 is a metal layer (e.g., copper) between the metal traces 308 and the interconnect 318. The UBM layer 316 forms the electrical connection between the metal traces 308 and interconnect 318 and serves as a barrier to eliminate unwanted diffusion. The interconnect 318 is a solder bump that connects to an external electronic device such a PCB.

In this example, the metal traces 308 do not include feet that flare out as described above and illustrated in FIGS. 1 and 2. Rather, undercuts 320 are formed under each side of the metal traces 308 where the metal trace 308 contacts the seed layers 304, 306. The undercuts are formed due the patterning of the photoresist material layer during fabrication. A foot is formed on the photoresist material layer where the photoresist material layer contacts the seed layers 304, 306. The foot thus forms the undercut 320 in the metal traces 308. The undercuts 320 in the metal traces 308 result in open circuits and current leakage in the IC package and a decrease in tolerance for pattern alignment due to exposure of the seed layers 304, 306.

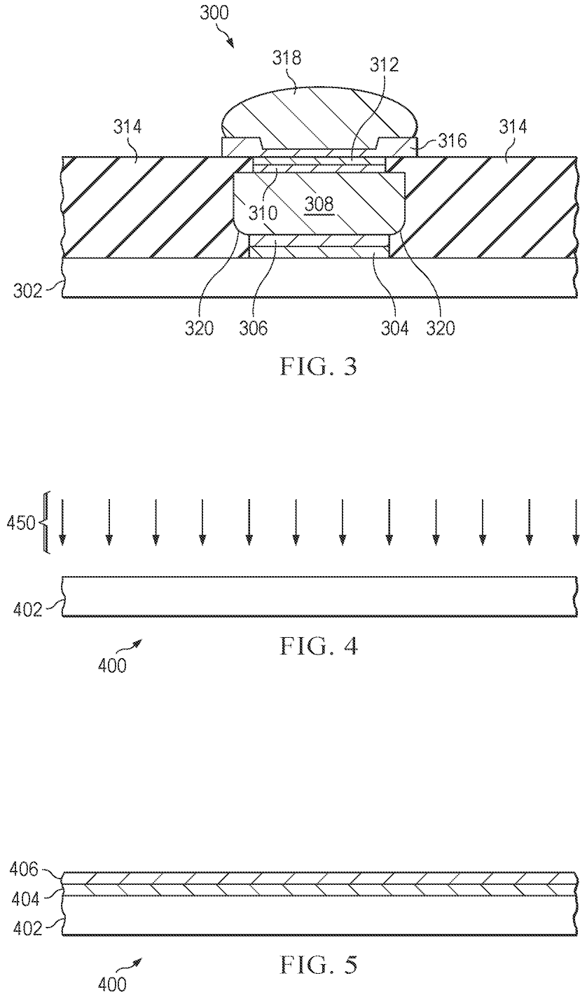

FIGS. 4-17 illustrate a fabrication process 400 associated with the formation of the electronic device 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 4-17 is an example method illustrating the example configuration of FIG. 1, other methods and configurations are possible. It is understood that although the method illustrated in FIGS. 4-17 depicts the fabrication process of a single IC package, the process applies to an array of IC packages. Thus, after fabrication of the IC packages the array is singulated to separate the IC packages from the array.

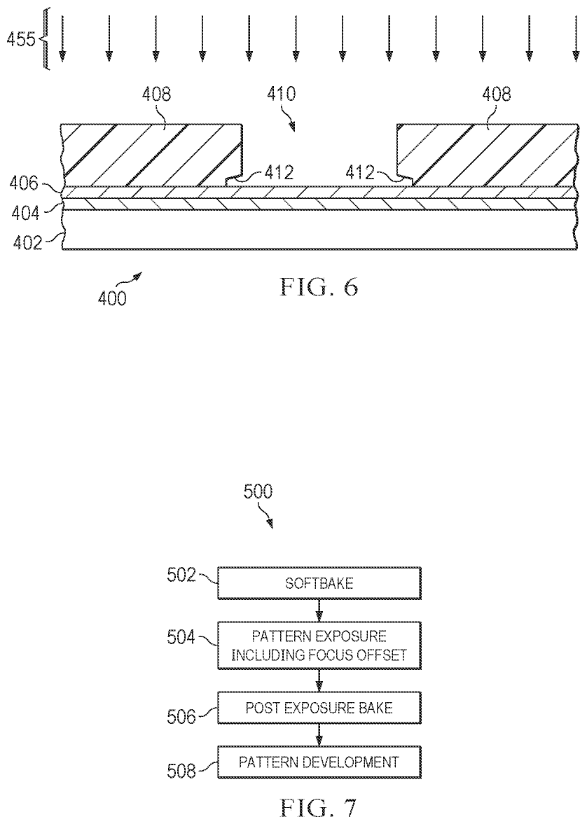

Referring to FIG. 4, the fabrication process 400 begins with a substrate (e.g., wafer) 402. A first seed layer 404 is deposited via a first metal deposition (e.g., sputtering) process 450 on a surface of the substrate 402 and an optional second seed layer 406 can be deposited via the first metal deposition process 450 onto a surface of the first seed layer 404 resulting in the configuration in FIG. 5. Referring to FIG. 6, a first photoresist material layer 408 overlies the first and second seed layers 404, 406 and is patterned and developed to expose a first opening 410 in the first photoresist material layer 408 in accordance with a pattern. The first photoresist material layer 408 can have a thickness that varies in correspondence with the wavelength of radiation used to pattern the first photoresist material layer 408. The first photoresist material layer 408 may be formed over the first and second seed layers 404, 406 via spin-coating or spin casting deposition techniques, selectively irradiated (e.g., via deep ultraviolet (DUV) irradiation) and developed to form the first opening 410.

As illustrated in FIG. 6, the first photoresist material layer 408 includes undercuts (recesses) 412 on each side of the first opening 410 where the first photoresist material layer 408 overlies the substrate 402 and contacts the first and second seed layers 404, 406. The undercuts 412 are formed via a specially formulated photoresist material that is chemically amplified and that undergoes a heating process 500 to from the undercuts 412. Specifically, referring to FIG. 7, the heating process 500 includes, at 502, performing a soft bake of the first photoresist material layer 408 at a temperature of approximately 120° C. for approximately 60 seconds. At 504, the first photoresist material layer 408 then undergoes a pattern exposure at an energy level ranging from approximately 310 mJ/cm² to 350 mJ/cm². During the exposure process, a focus offset is set to a range of approximately −6 to −12. The focus offset is a parameter that determines how the photoresist material layer pattern is printed. More specifically, the focus offset determines a side wall angle of the undercut 412. The higher the absolute value of the focus offset, the more that the undercut side wall is angled with respect to the first and second seed layers 404, 406. At 506, the first photoresist material layer 408 undergoes a post exposure bake at approximately 95° C. for approximately 90 seconds. Finally, at 508, the first photoresist material layer 408 is pattern developed four times for approximately 30 seconds.

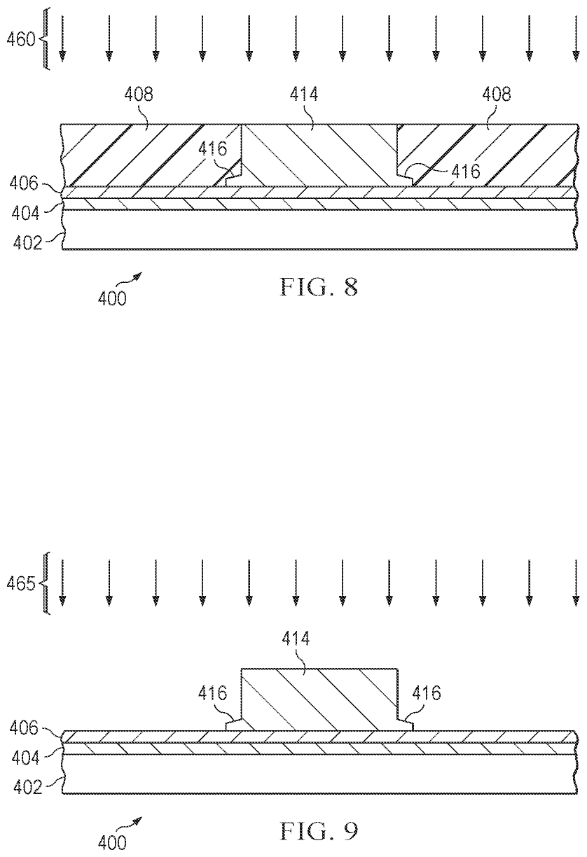

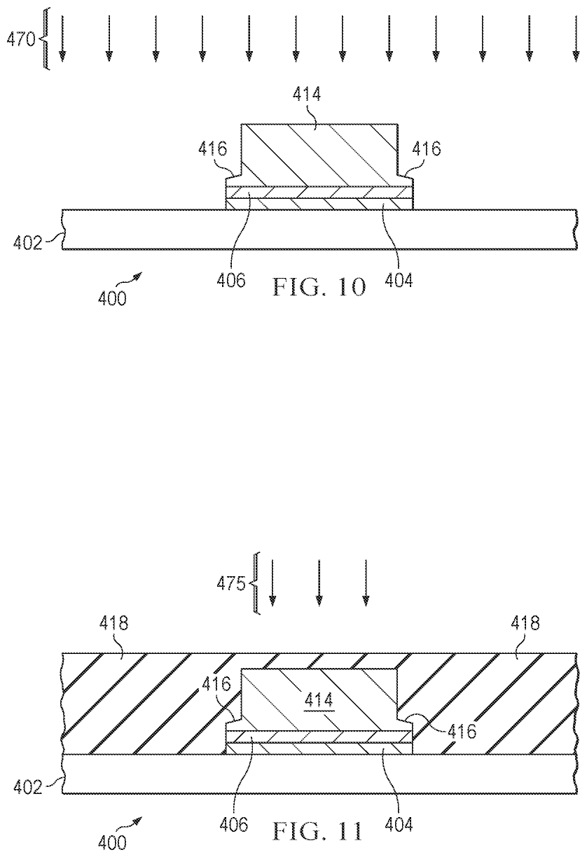

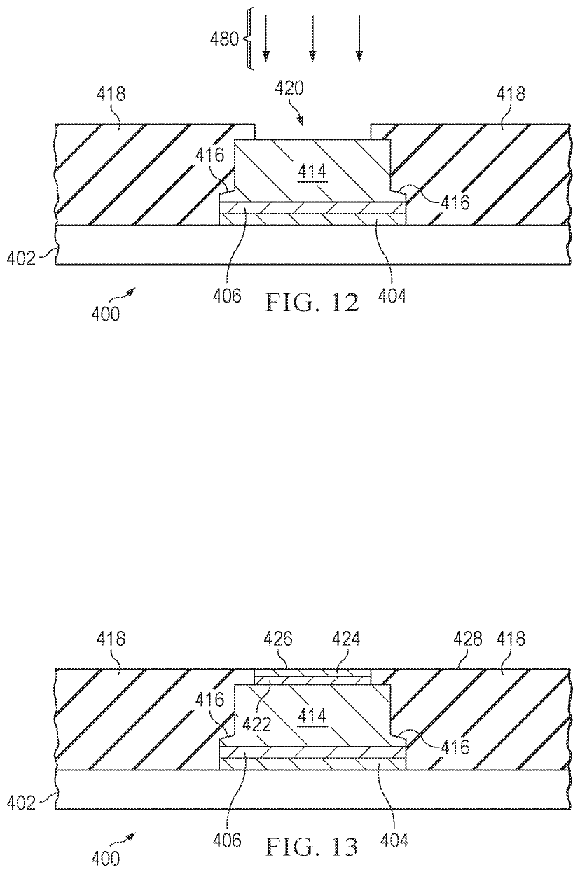

In the configuration in FIG. 6, a metal film or layer is deposited into the first opening 410 of the first photoresist material layer 408 via an electroplating process 455 thereby forming a metal trace 414 resulting in the configuration of FIG. 8. The metal film flows into the undercuts 412 of the first photoresist material layer 408 thereby forming feet 416 of the metal trace 414. The first photoresist material layer 408 is stripped via a first photoresist etching process 460 resulting in the configuration in FIG. 9. Exposed portions of the first and second seed layers 404, 406 are removed via a metal etching process 465 resulting in the configuration in FIG. 10. The configuration in FIG. 10 undergoes a deposition process 470 to form a dielectric or passivation layer (e.g., polyimide) 418 over the substrate 402 and the metal trace 414 resulting in the configuration in FIG. 11. The dielectric layer 418 is patterned 475 to form an opening 420 in the dielectric layer 418 over all or a portion of the metal trace 414 thereby exposing a surface of the metal trace 414 resulting in the configuration of FIG. 12. A third seed layer 422 is deposited via a second metal deposition (e.g., sputtering) process 480 in the opening 420 and on a surface of the metal trace 414. An optional fourth seed layer 424 can be deposited via the second metal deposition process 480 onto a surface of the third seed layer 422 resulting in the configuration in FIG. 13. The third and fourth seed layers 422, 424 form an interconnection metal layer that has a surface 426 that is substantially flush with a surface 428 of the dielectric layer 418.

Referring to FIG. 14, a second photoresist material layer 430 overlies the dielectric layer 418. The second photoresist material layer 430 is patterned and developed to expose a second opening 432 in the second photoresist material layer 430 in accordance with a pattern. The second photoresist material layer 430 can have a thickness that varies in correspondence with the wavelength of radiation used to pattern the second photoresist material layer 430. The second photoresist material layer 430 may be formed via spin-coating or spin casting deposition techniques, selectively irradiated (e.g., via deep ultraviolet (DUV) irradiation) and developed to form the second opening 432.

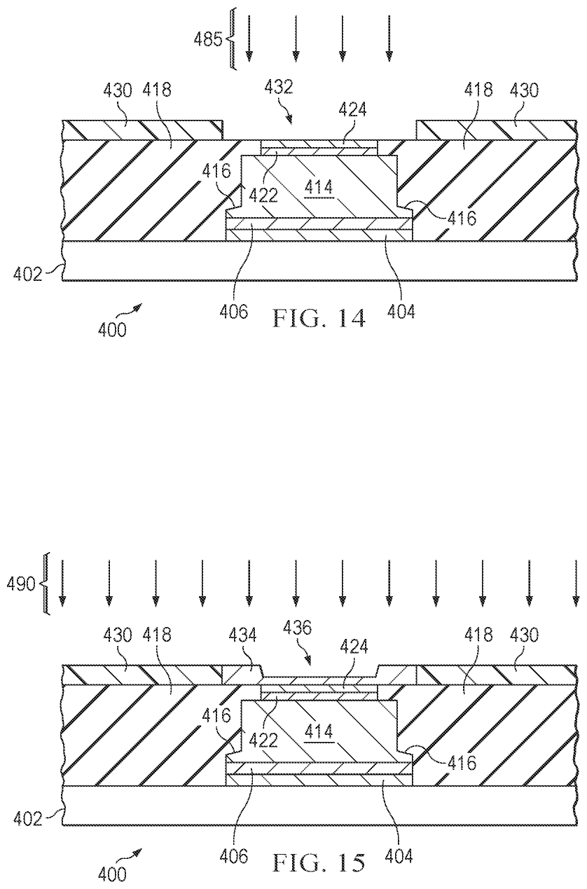

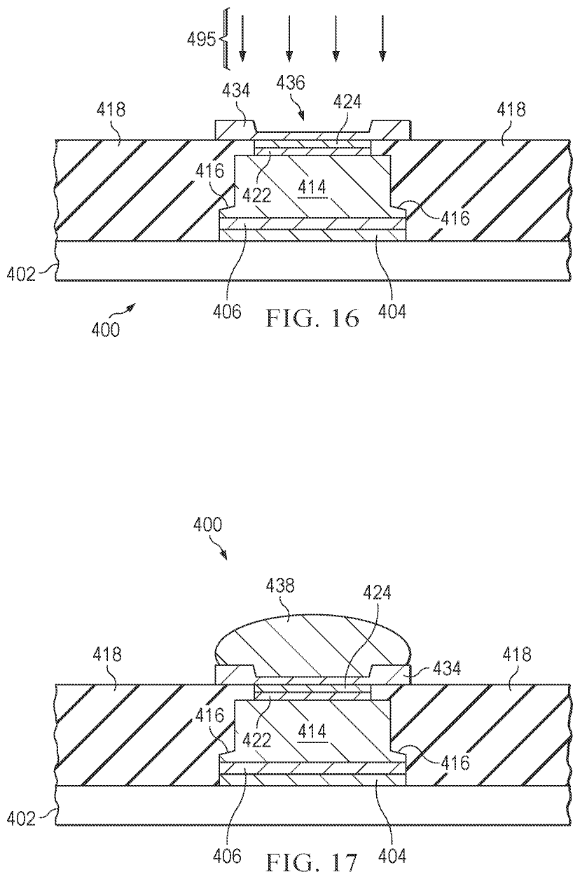

In the configuration of FIG. 14, an under bump metallization (UBM) layer 434 that includes a recess 436 is deposited via an electroplating process 485 onto a portion of the surface 428 of the dielectric layer 418 and the surface 426 of the interconnection metal layer 422, 424 resulting in the configuration in FIG. 15. The second photoresist material layer 430 is stripped via a second photoresist etching process 490 resulting in the configuration in FIG. 16. An interconnect (e.g., solder bump) 438 is deposited onto the UBM layer 434 via an evaporation or electroplating process 495 resulting in the configuration in FIG. 17.

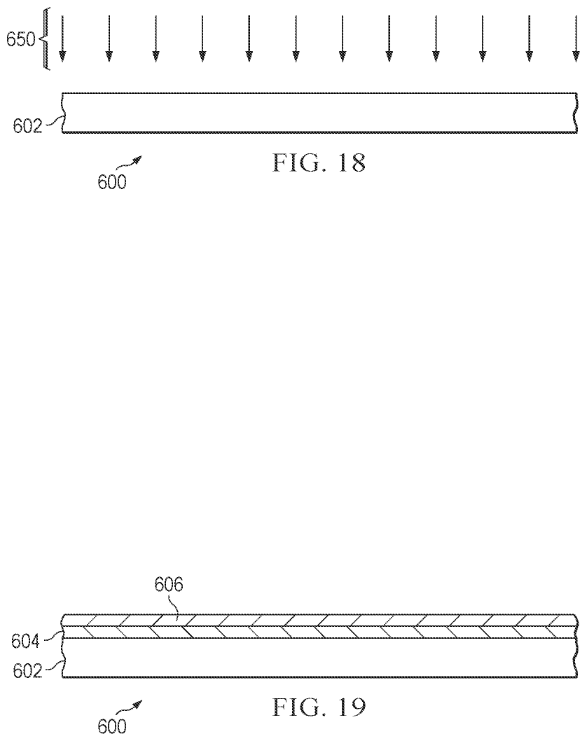

FIGS. 18-31 illustrate a fabrication process 600 associated with the formation of the electronic device 200 illustrated in FIG. 2. Though depicted sequentially as a matter of convenience, at least some of the actions shown can be performed in a different order and/or performed in parallel. Alternatively, some implementations may perform only some of the actions shown. Still further, although the example illustrated in FIGS. 18-31 is an example method illustrating the example configuration of FIG. 2, other methods and configurations are possible. It is understood that although the method illustrated in FIGS. 18-31 depicts the fabrication process of a single IC package, the process applies to an array of IC packages. Thus, after fabrication of the IC packages the array is singulated to separate the IC packages from the array.

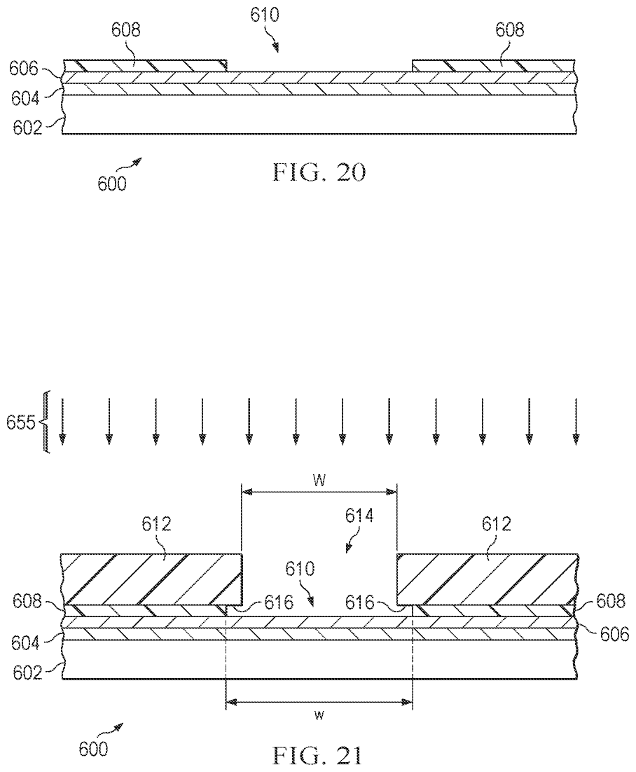

Referring to FIG. 18, the fabrication process 600 begins with a substrate (e.g., wafer). A first seed layer 604 is deposited on a surface of the substrate 602 via a first electroplating process 650 and an optional second seed layer 606 can be deposited on a surface of the first seed layer 604 via the first electroplating process 650 resulting in the configuration in FIG. 19. Referring to FIG. 20, a first photoresist material layer 608 overlies the first and second seed layers 604, 606 and is patterned and developed to expose a first opening 610 in the first photoresist material layer 608 in accordance with a pattern. The first photoresist material layer 608 can have a thickness that varies in correspondence with the wavelength of radiation used to pattern the first photoresist material layer 608. The first photoresist material layer 608 may be formed over the first and second seed layers 604, 606 via spin-coating or spin casting deposition techniques, selectively irradiated (e.g., via deep ultraviolet (DUV) irradiation) and developed to form the first opening 610.

Referring to FIG. 21, a second photoresist material layer 612 overlies the first photoresist material layer 608 and is patterned and developed to expose a second opening 614 in the second photoresist material layer 612 in accordance with a pattern. The second photoresist material layer 612 can have a thickness that varies in correspondence with the wavelength of radiation used to pattern the second photoresist material layer 612. The second photoresist material layer 612 may be formed over the first photoresist material layer 608 via spin-coating or spin casting deposition techniques, selectively irradiated (e.g., via deep ultraviolet (DUV) irradiation) and developed to form the second opening 614. The second opening 614 has width W that is smaller than a width w of the first opening 610. Thus, the second photoresist material layer 612 overhangs the first photoresist material layer 608. As a result, the stacked formation of both the first and second photoresist material layers 608, 612 form undercuts 616 on each side of the first opening 610 where the first photoresist material layer 608 overlies the substrate 602 and contacts the second seed layer 606.

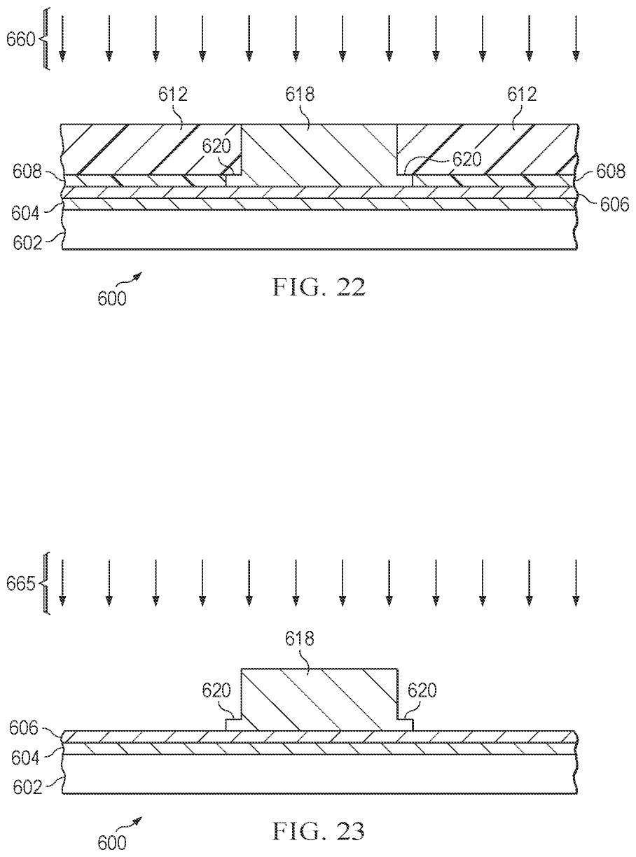

A metal film is deposited into the first and second opening 610, 614 of the first and second photoresist material layers 608, 612 respectively via an electroplating process 655 thereby forming metal trace 618 resulting in the configuration of FIG. 22. The metal film flows into the undercuts 616 formed by the stacking of the first and second photoresist material layers 608, 612 thereby forming feet 620 of the metal trace 618. The first and second photoresist material layers 608, 612 are stripped via a first photoresist etching process 660 resulting in the configuration in FIG. 23. Exposed portions of the first and second seed layers 604, 606 are removed via a metal etching process 665 resulting in the configuration in FIG. 24.

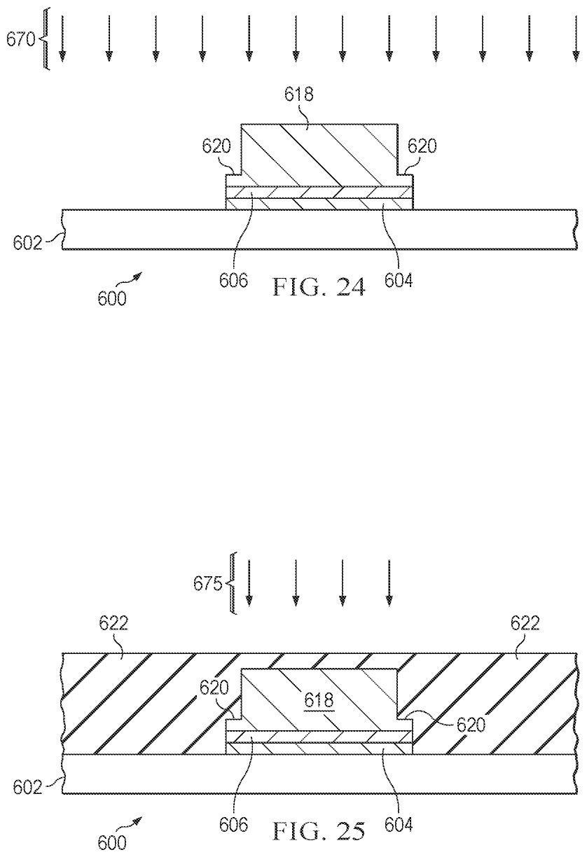

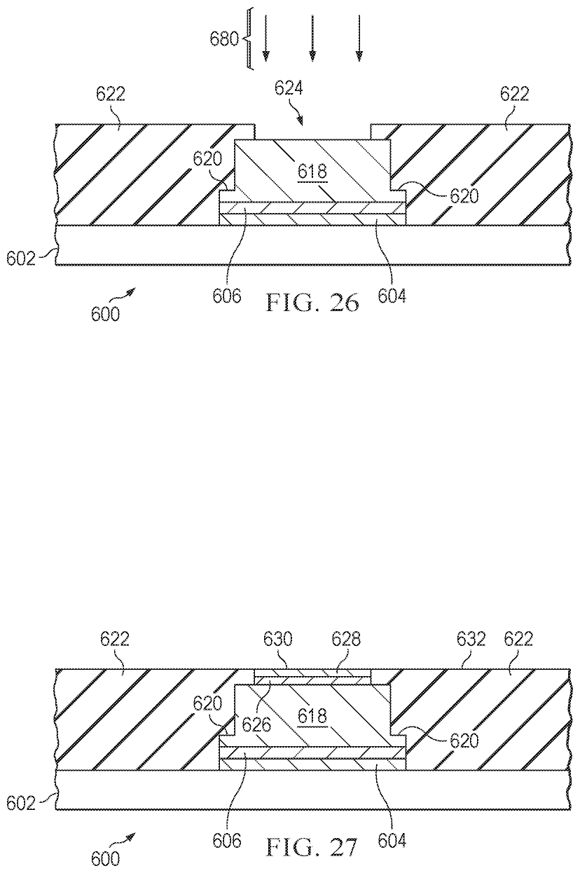

The configuration in FIG. 24 undergoes a deposition process 670 to form a dielectric or passivation layer (e.g., polyimide) 622 over the substrate 602 and the metal trace 618 resulting in the configuration in FIG. 25. The dielectric layer 622 is patterned 675 to form an opening 624 over all or a portion of the metal trace 618 in the dielectric layer 622 thereby exposing a surface of the metal trace 618 resulting in the configuration of FIG. 26. A third seed layer 626 is deposited via a second metal deposition (e.g., sputtering) process 680 on a surface of the metal trace 618. An optional fourth seed layer 628 can be deposited via the second metal deposition process 680 onto a surface of the third seed layer 626 resulting in the configuration in FIG. 27. The third and fourth seed layers 626, 628 form an interconnection metal layer that has a surface 630 that is substantially flush with a surface 632 of the dielectric layer 622.

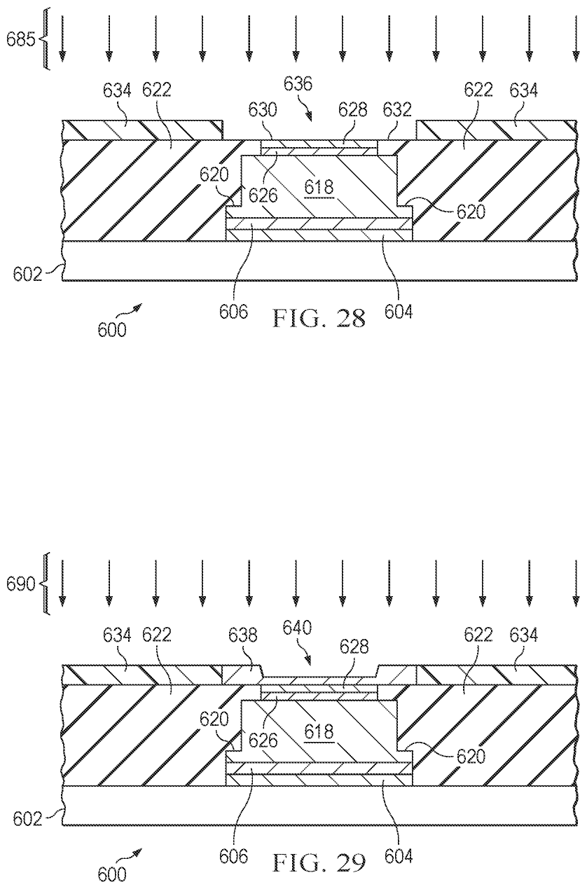

Referring to FIG. 28, a third photoresist material layer 634 overlies the dielectric layer 622. The third photoresist material layer 634 is patterned and developed to expose a third opening 636 in the third photoresist material layer 634 in accordance with a pattern. The third photoresist material layer 634 can have a thickness that varies in correspondence with the wavelength of radiation used to pattern the third photoresist material layer 634. The third photoresist material layer 634 may be formed via spin-coating or spin casting deposition techniques, selectively irradiated (e.g., via deep ultraviolet (DUV) irradiation) and developed to form the third opening 636.

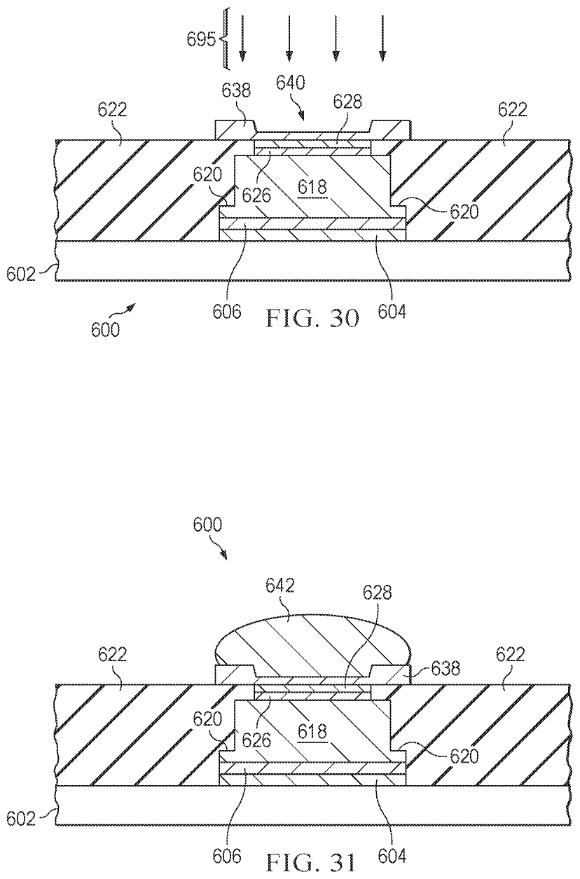

In the configuration of FIG. 28, an under bump metallization (UBM) layer 638 that includes a recess 640 is deposited via an electroplating process 685 onto a portion of the surface 632 of the dielectric layer 622 and the surface 630 of the interconnection metal layer 626, 628 resulting in the configuration in FIG. 29. The third photoresist material layer 634 is stripped via a second photoresist etching process 690 resulting in the configuration in FIG. 30. An interconnect (e.g., solder bump) 642 is deposited onto the UBM layer 638 via an evaporation or electroplating process 695 resulting in the configuration in FIG. 31.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
providing a substrate, the substrate including electrical circuits and/or electronic devices disposed thereon;
patterning at least one photoresist material layer overlying the substrate, the at least one photoresist material layer having at least one opening formed therein, the at least one photoresist material layer having undercuts formed on each side of the at least one opening where the at least one photoresist material layer overlies the substrate;
depositing a metal film in the at least one opening formed by the at least one photoresist material layer to form a metal trace, the metal trace forming a foot in the undercuts in the at least one opening formed by the at least one photoresist material layer;
forming a dielectric layer overlying the substrate; and
depositing an interconnect on the metal trace.

2. The method of claim 1, wherein patterning at least one photoresist material layer overlying the substrate comprises:
performing a soft bake of the at least one photoresist material layer at a temperature of approximately 120° C. for approximately 60 seconds;
performing a pattern exposure at an energy level ranging from approximately 310 mJ/cm² to 350 mJ/cm²;
setting a focus offset to a range of approximately −6 to −12;
performing a post exposure bake at approximately 95° C. for approximately 90 seconds; and
patterning the at least one photoresist material layer a plurality of times for approximately 30 seconds.

3. The method of claim 1, wherein prior to patterning at least one photoresist material layer overlying the substrate, the method comprising depositing at least one seed layer on a surface of the substrate.

4. The method of claim 3, wherein prior to forming a dielectric layer overlying the substrate, the method further comprising removing the at least one photoresist material layer via a first etching process.

5. The method of claim 4 further comprising removing exposed portions of the at least one seed layer via a metal etching process.

6. The method of claim 5, wherein forming the dielectric layer includes depositing the dielectric layer over the substrate and the metal trace and patterning the dielectric layer to form an opening over all or a portion of the metal trace.

7. The method of claim 6 further comprising depositing an interconnection metal layer in the opening of the dielectric layer and on a surface of the metal trace.

8. The method of claim 7 further comprising patterning a second photoresist material layer overlying the dielectric layer to form an opening over the interconnection metal layer.

9. The method of claim 8, further comprising depositing an under bump metallization layer in the opening of the second photoresist material layer and on the at least one interconnection metal layer and removing the second photoresist material layer via a second etching process.

10. The method of claim 1, wherein the at least one photoresist material layer is a first photoresist material layer and the at least one opening is at least one first opening, the method further comprising patterning a second photoresist material layer on a surface of the first photoresist material layer, the second photoresist material layer having at least one second opening aligned with the at least one first opening formed in the first photoresist material layer, the at least one second opening having a width smaller than a width of the at least one first opening thereby forming undercuts on each side of the at least one first opening where the first photoresist material layer overlies the substrate.

11. The method of claim 10, wherein prior to patterning at least one photoresist material layer overlying the substrate, the method comprising depositing at least one seed layer on a surface of the substrate.

12. The method of claim 11, wherein prior to forming a dielectric layer overlying the substrate, the method further comprising removing the first and second photoresist material layers via a first etching process.

13. The method of claim 12 further comprising removing exposed portions of the at least one seed layer via a metal etching process.

14. The method of claim 13, wherein forming the dielectric layer includes depositing the dielectric layer over the substrate and the metal trace and patterning the dielectric layer to form an opening over all or a portion of the metal trace.

15. The method of claim 14 further comprising depositing an interconnection metal layer in the opening of the dielectric layer and on a surface of the metal trace.

16. The method of claim 15, further comprising patterning a third photoresist material layer overlying the dielectric layer.

17. The method of claim 16, further comprising depositing an under bump metallization layer on the at least one interconnection metal layer and removing the third photoresist material layer via a second etching process.

18. An electronic device comprising:
a substrate having electrical circuits and/or electronic devices disposed thereon;
metal traces formed on the substrate, the metal traces including feet on each side of the metal traces that flare outward in opposite directions from each other where the metal traces overlie the substrate;
a dielectric layer formed on the substrate and a portion of the metal traces; and
an interconnect disposed on the metal traces.

19. The electronic device of claim 18, further comprising at least one seed layer disposed on a surface of the substrate.

20. The electronic device of claim 19, further comprising an interconnection metal layer disposed on the metal traces and an under bump metallization layer disposed on a surface of the interconnection metal layer.
